(19) United States
(12) Patent Application Publication
(10) Pub. No.: US 2026/0333771 A1
(43) Pub. Date: Oct. 22, 2026

(54) SEMICONDUCTOR DEVICE, ELECTRONIC APPARATUS INCLUDING THE SAME AND METHOD OF MANUFACTURING THE SAME

(71) Applicant: Samsung Electronics Co., Ltd., Suwon-si (KR)

(72) Inventors: Minwoo CHOI, Suwon-si (KR); Yongyoung PARK, Suwon-si (KR); Hajun SUNG, Suwon-si (KR); Kiyeon YANG, Suwon-si (KR); Younjin JANG, Suwon-si (KR)

(73) Assignee: Samsung Electronics Co., Ltd., Suwon-si (KR)

(21) Appl. No.: 19/543,361

(22) Filed: Feb. 18, 2026

(30) Foreign Application Priority Data
Apr. 18, 2025 (KR) 10-2025-0050964

(51) Int. Cl. H10D 30/67; H10B 12/00; H10B 51/10; H10B 51/20; H10B 51/30; H10D 30/00; H10D 30/01

(52) U.S. Cl. CPC H10D 30/675; H10B 12/00; H10B 12/01; H10D 30/0314; H10D 30/502; H10D 30/6728; H10D 30/6731; H10D 30/6735; H10D 30/6736; H10D 30/6748; H10D 30/6757; H10B 51/10; H10B 51/20; H10B 51/30

(57) ABSTRACT

Provided are semiconductor devices, electronic devices including the same, and methods of manufacturing the semiconductor device. A semiconductor device includes a channel, a source electrode electrically connected to the channel, a drain electrode electrically connected to the channel and spaced apart from the source electrode, a gate insulating layer on the channel, and a gate electrode on the gate insulating layer, wherein the channel includes TeₐSe_{b}O_{c} (a+b+c=100, 40≤a<100, 0<b≤30, and 0<c≤30).

### CROSS-REFERENCE TO RELATED APPLICATION

This application is based on and claims priority under 35 U.S.C. § 119 to Korean Patent Application No. 10-2025-0050964, filed on Apr. 18, 2025, in the Korean Intellectual Property Office, the disclosure of which is incorporated by reference herein in its entirety.

### BACKGROUND

### 1. Field

Example embodiments relate to semiconductor devices including a p-type channel, electronic apparatuses including the same, and/or methods of manufacturing the semiconductor device.

### 2. Description of the Related Art

Most oxide semiconductors having relatively high electrical performance used for semiconductor devices are n-type semiconductors that efficiently transfer electrons at room temperature, and the development of p-type semiconductors capable of transferring holes has limitations in various application fields. For example, InGaZnO is widely used for n-type semiconductors, and InGaZnO is applied to backplane transistors that drive organic light-emitting diode (OLED) displays.

Materials such as SnO have been studied as p-type oxide semiconductors, but SnO has lower hole field effect mobility and a lower on/off current ratio than an n-type oxide semiconductor. Research on p-type oxide semiconductors with excellent or relatively good electrical characteristics may be advantageous and such p-type oxide semiconductors may be used in various semiconductor devices.

### SUMMARY

Some example embodiment provide semiconductor devices including a p-type channel.

Some example embodiment provide electronic apparatuses including a semiconductor device including a p-type channel.

Some example embodiment provide methods of manufacturing a semiconductor device including a p-type channel.

Additional aspects will be set forth in part in the description which follows and, in part, will be apparent from the description, or may be learned by practice of the presented example embodiments of the disclosure.

According to an example embodiment of the disclosure, a semiconductor device includes a channel, a source electrode electrically connected to the channel, a drain electrode electrically connected to the channel and spaced apart from the source electrode, a gate insulating layer on the channel, and a gate electrode on the gate insulating layer, wherein the channel includes TeₐSe_{b}O_{c} (a+b+c=100, 40≤a<100, 0<b≤30, and 0<c≤30).

The channel may have a composition of 0.05≤(b/a)≤0.8.

The channel may have a structure in which at least two layers of a tellurium layer, a tellurium oxide layer, a selenium layer, or a selenium oxide layer are alternately stacked.

The channel may further include at least one of S, Se, In, Ge, Sn, Cu, Sb, As, B, P, or Al.

A first direction from the source electrode to the drain electrode may be same as a vertical direction of the semiconductor device, and longitudinal directions of the channel, the gate insulating layer, and the gate electrode may be arranged in the first direction.

The channel may include a bottom portion in contact with the source electrode, a first vertical extension portion extending from one end of the bottom portion in a direction perpendicular to the source electrode, and a second vertical extension portion extending from another end of the bottom portion in a direction perpendicular to the source electrode.

The channel, the gate insulating layer, and the gate electrode may be arranged in a concentric shape, and the gate electrode may include a first gate electrode and a second gate electrode that are spaced apart from each other, and a spacer may be arranged between the first gate electrode and the second gate electrode.

The channel may include a plurality of channels, and have a multi-bridge shape in which the plurality of channels are in contact with the source electrode and the drain electrode and are stacked to be spaced apart from each other in a direction away from a substrate.

According to an example embodiment of the disclosure, an electronic apparatus includes a host, a memory device including at least one semiconductor device, and a memory controller configured to control the memory device for at least one of reading data from the memory device or writing data to the memory device in response to a request from the host, wherein the at least one semiconductor device includes a channel, a source electrode electrically connected to the channel, a drain electrode electrically connected to the channel and spaced apart from the source electrode, a gate insulating layer on the channel, and a gate electrode on the gate insulating layer, and the channel includes TeₐSe_{b}O_{c} (a+b+c=100, 40≤a<100, 0<b≤30, and 0<c≤30).

According to an example embodiment of the disclosure, a method of manufacturing a semiconductor device includes forming a channel on a substrate, adjusting a composition of the channel to TeₐSe_{b}O_{c} (a+b+c=100, 40≤a<100, 0<b≤30, and 0<c≤30), forming a source electrode on one surface of the channel and forming a drain electrode on another surface of the channel, forming a gate insulating layer on the channel, and forming a gate electrode on the gate insulating layer.

### BRIEF DESCRIPTION OF THE DRAWINGS

The above and other aspects, features, and advantages of certain example embodiments of the disclosure will be more apparent from the following description taken in conjunction with the accompanying drawings, in which:

FIG. 1 is a cross-sectional view of a semiconductor device according to an example embodiment;

FIG. 2A, FIG. 2B, and FIG. 2C illustrate transfer curves according to changes in the contents of tellurium and selenium in a channel of a semiconductor device according to an example embodiment;

FIG. 3 illustrates mobility and Ion/I_{off} according to the content of selenium in a channel of a semiconductor device according to an example embodiment;

FIG. 4A illustrates a transfer curve when an oxygen content in a channel of a semiconductor device according to an example embodiment is 29 at %;

FIG. 4B illustrates a transfer curve when an oxygen content in a channel of a semiconductor device according to an example embodiment is 24 at %;

FIG. 4C illustrates a transfer curve when an oxygen content in a channel of a semiconductor device according to an example embodiment is 19 at %.

FIG. 5A illustrates transconductance for a gate voltage when an oxygen content in a channel of a semiconductor device according to an example embodiment is 24 at %;

FIG. 5B illustrates transconductance for a gate voltage when an oxygen content in a channel of a semiconductor device according to an example embodiment is 19 at %;

FIG. 6 illustrates mobility when an oxygen content in a channel of a semiconductor device according to an example embodiment is 24 at % and 19 at %;

FIGS. 7, 8, and 9 illustrates examples of semiconductor devices, each having a vertical channel structure;

FIG. 10 is a horizontal cross-sectional view schematically illustrating a structure of a memory cell string of a memory device according to an example embodiment;

FIG. 11 is a vertical cross-sectional view of FIG. 10;

FIG. 12 illustrates a semiconductor device having a multi-channel structure, according to an example embodiment;

FIG. 13 is a flowchart illustrating a method of manufacturing a semiconductor device, according to an example embodiment;

FIG. 14 illustrates a memory device to which a semiconductor device according to an example embodiment is applied;

FIG. 15 illustrates voltages of respective electrical lines of a unipolar 2T0C dynamic random access memory (DRAM) based on an n-type channel;

FIG. 16 illustrates voltages of respective electrical lines of a 2TOC DRAM including an n-type MOS and a p-type MOS;

FIG. 17 is a diagram illustrating an equivalent circuit of a memory device according to an example embodiment;

FIG. 18 is a conceptual diagram schematically illustrating a device architecture that may be applied to an electronic apparatus;

FIG. 19 is a block diagram of a memory system according to an example embodiment; and

FIG. 20 is a block diagram illustrating a neuromorphic device according to an example embodiment and an external device connected thereto.

### DETAILED DESCRIPTION

Reference will now be made in detail to example embodiments, examples of which are illustrated in the accompanying drawings, wherein like reference numerals refer to like elements throughout. In this regard, the present example embodiments may have different forms and should not be construed as being limited to the descriptions set forth herein. Accordingly, the example embodiments are merely described below, by referring to the figures, to explain aspects. As used herein, the term “and/or” includes any and all combinations of one or more of the associated listed items. Expressions such as “one of,” “one or more of,” “any one of,” “at least one of,” “at least two of” and “at least one selected from” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Hereinafter, semiconductor devices, electronic apparatuses including the semiconductor device, and methods of manufacturing the semiconductor device are described in detail with reference to the attached drawings. In the following drawings, the same reference numerals refer to the same components, and a size of each component in the drawings may be exaggerated for the sake of clear and convenient description. Terms, such as first, second, and so on may be used to describe various components, but the components should not be limited by the terms. Terms are used only for the purpose of distinguishing one component from another component.

Singular expressions include plural expressions unless the context clearly indicates otherwise. Also, when a portion is said to “include” a component, this does not mean that the portion excludes other components unless otherwise specifically stated, but rather that the portion may include other components. Also, sizes or thicknesses of respective components in the drawings may be exaggerated for clarity of description. Also, when a certain material layer is described as existing on a substrate or another layer, the material layer may exist in direct contact with the substrate or another layer, or a third layer may exist therebetween. Also, because the materials forming respective layers in the example embodiments below are examples, other materials may be used therefor.

Also, terms “ . . . portion/unit”, “module”, or so on described in the specification mean a unit that processes at least one function or operation, which may be implemented with hardware or software, or a combination of hardware and software.

The specific implementations described in the example embodiments are examples and do not limit the technical scope in any way. In order to simplify the specification, descriptions of conventional electronic components, control systems, software, and other functional aspects of the above systems may be omitted. Also, connections or lack of connections between the components illustrated in the drawings are merely examples of functional connections and/or physical or circuit connections, and may be represented in actual devices as alternative or additional various functional connections, physical connections, or circuit connections.

As used herein, the singular forms “a,” “an,” and “the” are intended to include the plural forms as well, unless the context clearly indicates otherwise.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present.

Operations of methods may be performed in any suitable order unless there is an explicit statement that the operations have to be performed in the order described. Also, the use of all example terms (for example, and so on) is intended merely to describe the technical idea and does not limit the scope of the claims by such terms unless otherwise defined by the claims.

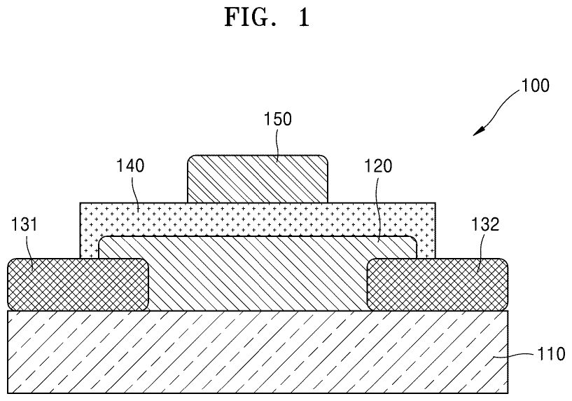

FIG. 1 schematically illustrates a semiconductor device according to an example embodiment.

The semiconductor device 100 includes a substrate 110, a channel 120 provided on the substrate 110, a source electrode 131 electrically connected to the channel 120, a drain electrode 132 electrically connected to the channel 120, a gate insulating layer 140 provided on the channel 120, and a gate electrode 150 provided on the gate insulating layer 140.

The source electrode 131 may be spaced apart from the drain electrode 132. The channel 120 may extend to a part of an upper surface of the source electrode 131 and a part of an upper surface of the drain electrode 132. The semiconductor device 100 may be applied to a transistor having a planar channel structure.

The substrate 110 may be an insulating substrate, or may be a semiconductor substrate having an insulating layer formed on a surface thereof. In some example embodiments, the substrate 110 may be a semiconductor substrate. The semiconductor substrate may include, for example, Si, Ge, SiGe, or a III-V group semiconductor material. The substrate 110 may be, for example, a silicon substrate having silicon oxide formed on a surface thereof but is not limited thereto.

The channel 120 may include tellurium (Te), selenium (Se), and oxygen (O). The channel 120 may be a p-type channel including TeₐSe_{b}O_{c} (a+b+c=100, 40≤a<100, 0<b≤30, and 0<c≤30). The channel 120 may further include at least one of S, Se, In, Ge, Sn, Cu, Sb, As, B, P, or Al. The elements may be included as dopants. The channel 120 may include a single layer of TeₐSe_{b}O_{c}. However, the channel 120 is not limited thereto, and may also have a structure in which at least two of a tellurium layer, a tellurium oxide layer, a selenium layer, or a selenium oxide layer are alternately stacked. For example, the channel 120 may have a structure in which a tellurium layer and a tellurium oxide layer are alternately stacked, or a structure in which a tellurium layer, a tellurium oxide layer, a selenium layer, and a selenium oxide layer are alternately stacked. The channel 120 may have a thickness in a range of about 1 to about 100 nm. Also, the channel 120 may have an amorphous structure.

The source electrode 131 and the drain electrode 132 may each include a metal material. The source electrode 131 and the drain electrode 132 may each include at least one of tungsten (W), cobalt (Co), nickel (Ni), iron (Fe), titanium (Ti), molybdenum (Mo), chromium (Cr), zirconium (Zr), hafnium (Hf), niobium (Nb), tantalum (Ta), silver (Ag), gold (Au), aluminum (Al), copper (Cu), tin (Sb), vanadium (V), ruthenium (Ru), platinum (Pt), zinc (Zn), or magnesium (Mg). In some example embodiments, the source electrode 131 and the drain electrode 132 may each include nitride including the above materials. The source electrode 131 and the drain electrode 132 may each include at least one of, for example, W, TiN, Mo, MoN, Ru, or TiSiN. The source electrode 131 and the drain electrode 132 may each include, for example, Zn having a content of about 10 at % or less. Here, the Zn content may represent a content of Zn relative to the total metal elements included in the source electrode 131 excluding oxygen.

The gate electrode 150 may include at least one of metal, metal nitride, or transparent conductive oxide (TCO). The gate insulating layer 140 may include an oxide material including at least one of hafnium (Hf), zirconium (Zr), aluminum (Al), or silicon (Si). When the semiconductor device 100 is a component of a memory cell, the gate electrode 150 may be a part of a word line.

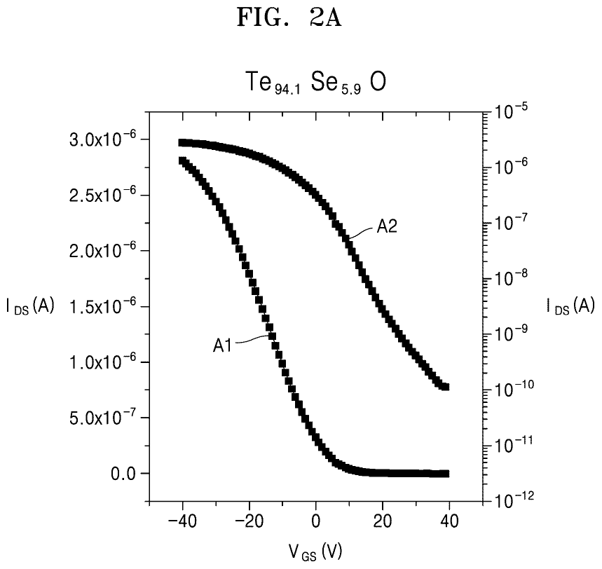

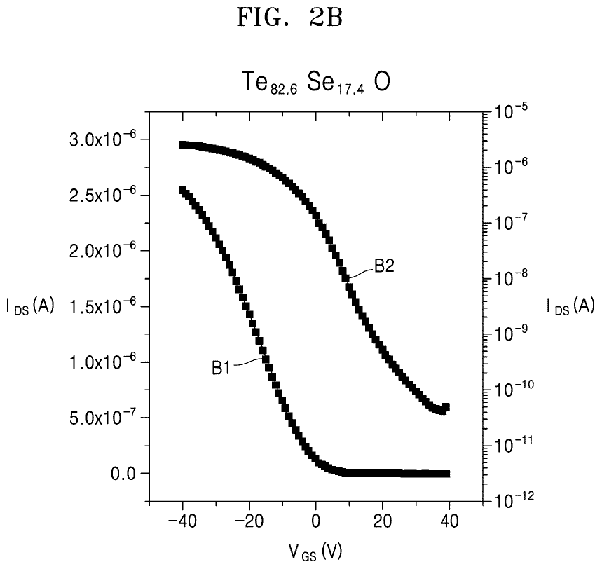

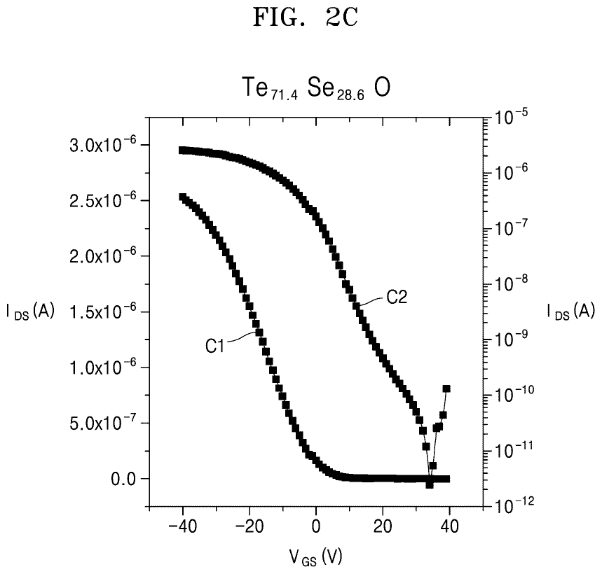

FIGS. 2A, 2B, and 2C illustrate transfer curves according to changes in content of tellurium (Te) and selenium (Se) in the channel 120 of the semiconductor device 100.

FIG. 2A illustrates a transfer curve when the channel 120 includes Te_{94.1}Se_{5.9}O. A graph A1 has a linear scale, and a graph A2 has a log scale. In a Te_{94.1}Se_{5.9}O channel, an on-current appears when VGS has a (−) value, and accordingly, p-type semiconductor characteristics appear. FIG. 2B illustrates a transfer curve when Te_{82.6}Se_{17.4}O is included, and a graph B1 has a linear scale, and a graph B2 has a log scale. In a Te_{82.6}Se_{17.4}O channel, an on-current appears when VGS has a (−) value, and accordingly, p-type semiconductor characteristics appear. FIG. 2C illustrates a transfer curve when Te_{71.4}Se_{28.6}O is included, and a graph C1 has a linear scale, and a graph C2 has a log scale. In a Te_{71.4}Se_{28.6}O channel, an on-current appears when V_{GS} has a (−) value, and accordingly, p-type semiconductor characteristics appear.

Referring to FIGS. 2A, 2B, and 2C, the channel 120 may include TeₐSe_{b}O_{c}, wherein 40≤a≤100 and 0≤b≤30. In some example embodiments, the channel 120 may include TeₐSe_{b}O_{c}, wherein 50≤a<100 and 0<b≤30.

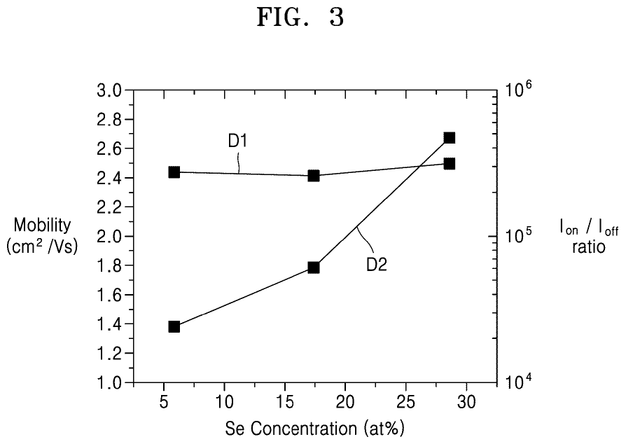

FIG. 3 illustrates hole mobility and Iₒₙ/I_{off} according to a Se content. A graph D1 represents mobility, and a graph D2 represents Iₒₙ/I_{off}. While a Se content changes up to 30 at %, the mobility is maintained to be higher than 2.0 (Cm²/Vs), and the Iₒₙ/I_{off} gradually increase. Referring to FIG. 3, when the Se content is 30 at % or less, improved or excellent mobility and Ion/Ioff may be obtained. When the Se content is 30 at % or less, an off-current may increase compared to a decrease of the on-current.

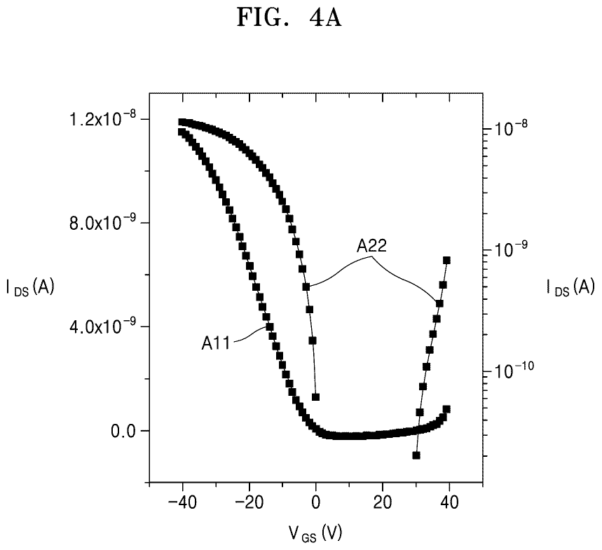

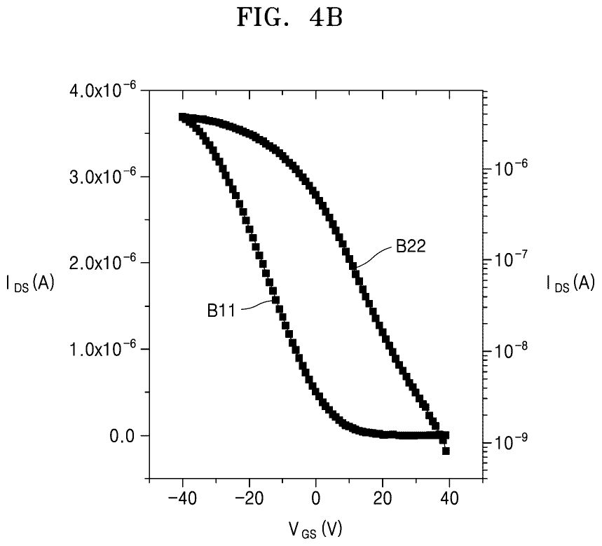

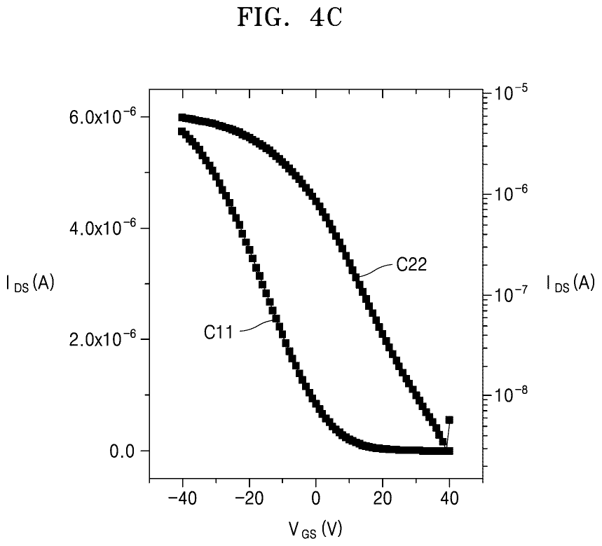

FIGS. 4A, 4B, and 4C illustrate transfer curves according to a change in oxygen content of the channel 120 in the semiconductor device 100.

FIG. 4A illustrates a transfer curve when an oxygen content c of TeₐSe_{b}O_{c} is 29 at %, and an on-current appears when VGS has a (−) value, and accordingly, p-type semiconductor characteristics appear. A graph A11 has a linear scale, and a graph A22 has a log scale.

FIG. 4B illustrates a transfer curve when an oxygen content c of TeₐSe_{b}O_{c} is 24 at %, and an on-current appears when VGS has a (−) value, and accordingly, p-type semiconductor characteristics appear. A graph B11 has a linear scale, and a graph B22 has a log scale.

FIG. 4C illustrates a transfer curve when an oxygen content c of TeₐSe_{b}O_{c} is 19n at %. In a Te₇₁O₁₉ channel, an on-current appears when V_{GS} has a (−) value, and accordingly, p-type semiconductor characteristics appear. A graph C11 has a linear scale, and a graph C22 has a log scale.

Referring to FIGS. 4A, 4B, and 4C, an on-current increases as an oxygen content of the TeₐSe_{b}O_{c} channel 120 decreases. An oxygen content c of the TeₐSe_{b}O_{c} channel 120 may have a range of about 30 at % or less. In some example embodiments, the oxygen content c may have a range greater than 0 and less than or equal to 30 at %.

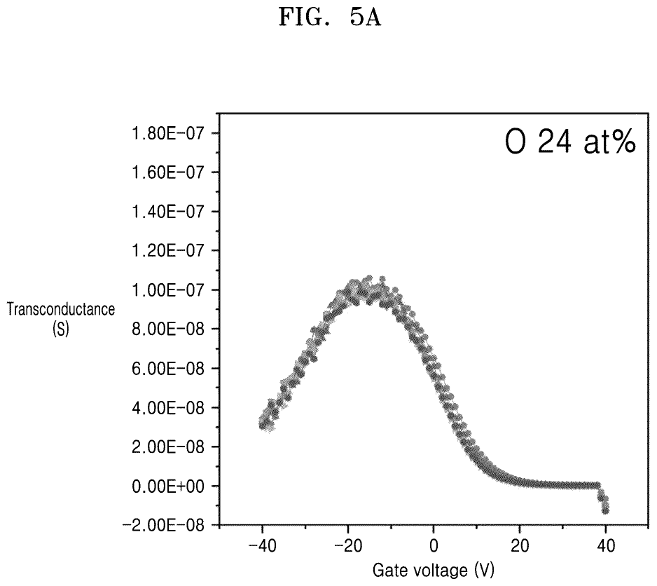

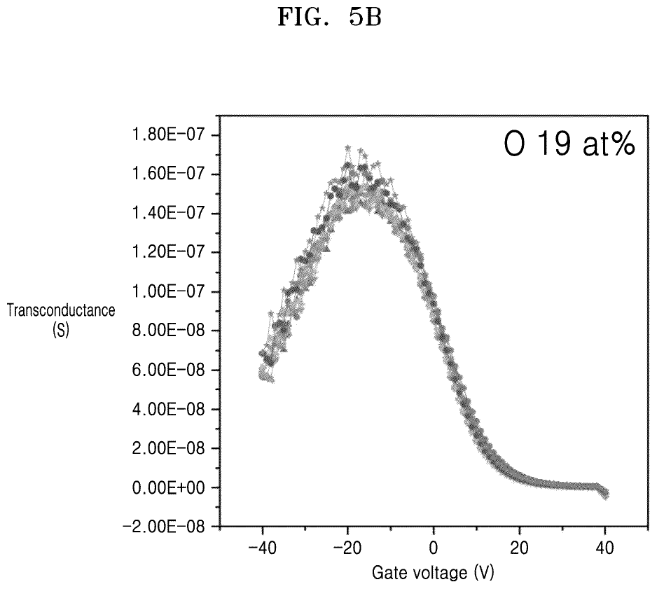

FIG. 5A illustrates transconductance for a gate voltage when an oxygen content of the TeₐSe_{b}O_{c} channel 120 is 24 at %. FIG. 5B illustrates transconductance for a gate voltage when the oxygen content of the TeₐSe_{b}O_{c} channel 120 is 19 at %. Referring to FIGS. 5A and 5B, it may be seen that the transconductance increases as the oxygen content of the TeₐSe_{b}O_{c} channel 120 decreases.

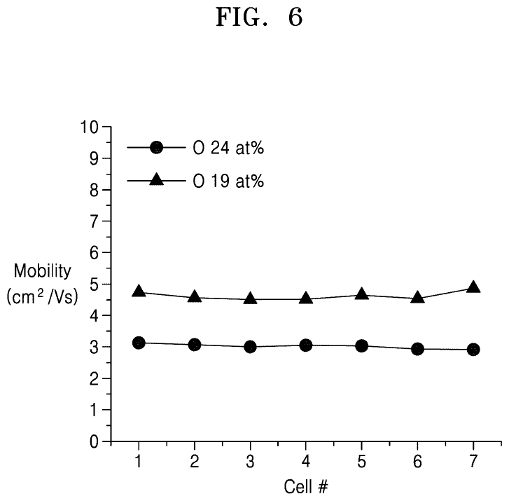

FIG. 6 illustrates mobility when the oxygen content of the TeₐSe_{b}O_{c} channel 120 is 24 at % and 19 at %. A horizontal axis of a graph represents a Cell number, and the Cell represents a test specimen. The TeₐSe_{b}O_{c} channel 120 has mobility of about 3 cm²/Vs or more when the oxygen content is 24 at % and 19 at %, and relatively high mobility appears when the oxygen content is 19 at % than when the oxygen content is 24 at %. Referring to FIG. 6, it may be seen that the mobility increases as the oxygen content of the TeₐSe_{b}O_{c} channel 120 decreases.

As described above, the semiconductor device 100 according to an example embodiment has a p-type channel including TeₐSe_{b}O_{c} (a+b+c=100, 40≤a<100, 0<b≤30, and 0<c≤30), and may have a relatively large on-current, relatively large transconductance, and/or relatively large mobility. Also, the channel 120 in the semiconductor device 100 may have a composition satisfying 0.05≤(b/a)≤0.8.

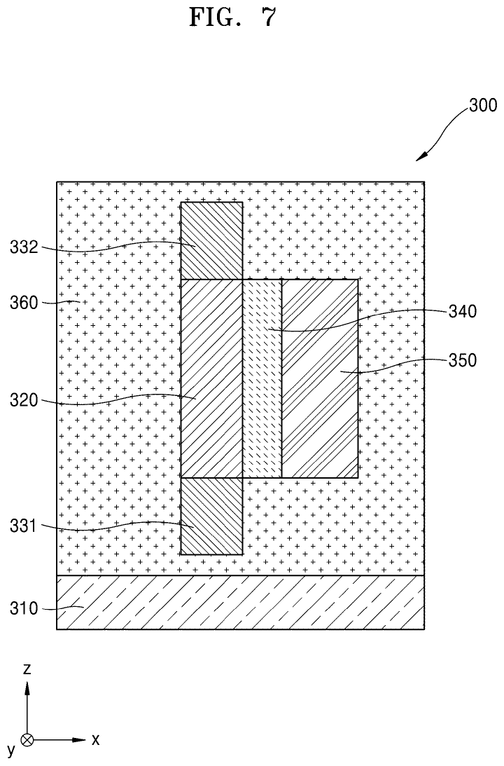

FIG. 7 illustrates a semiconductor device according to another example embodiment.

Referring to FIG. 7, a semiconductor device 300 includes a substrate 310, a source electrode 331 provided on the substrate 310, a drain electrode 332 provided spaced apart from the source electrode 331, and a channel 320 arranged between the source electrode 331 and the drain electrode 332.

The channel 320 may include TeₐSe_{b}O_{c} (a+b+c=100, 40≤a<100, 0<b≤30, and 0<c≤30). The channel 320 may further include at least one of S, Se, In, Ge, Sn, Cu, Sb, As, B, P, or Al.

The source electrode 331 and the drain electrode 332 are arranged to be spaced apart from each other in a direction (the z direction) perpendicular to the substrate 310, and the source electrode 331, the channel 320, and the drain electrode 332 may be arranged in a row in a direction (the z direction) perpendicular to the substrate 310. The source electrode 331, the channel 320, and the drain electrode 332 may be arranged sequentially without the intervention of other layers. The source electrode 331, the channel 320, and the drain electrode 332 may have the same width. The channel 320 may be arranged such that a length direction is a direction (the z direction) perpendicular to the substrate 310. In the description, the length direction indicates a direction in which a length of a corresponding component is longer when viewed in the drawings. The semiconductor device 300 may be applied to a vertical channel transistor.

A gate electrode 350 may be provided on one side of the channel 320. A gate insulating layer 340 may be provided between the channel 320 and the gate electrode 350. The gate electrode 350 may be arranged such that a length direction (the z direction) is perpendicular to the substrate 310. The channel 320, the gate insulating layer 340, and the gate electrode 350 may be arranged in a row in a direction horizontal to the substrate 310 (the x direction). A mold insulating layer 360 may be provided on the substrate 310 to fill a free space. The source electrode 331 may be spaced apart from the substrate 310 by the mold insulating layer 360.

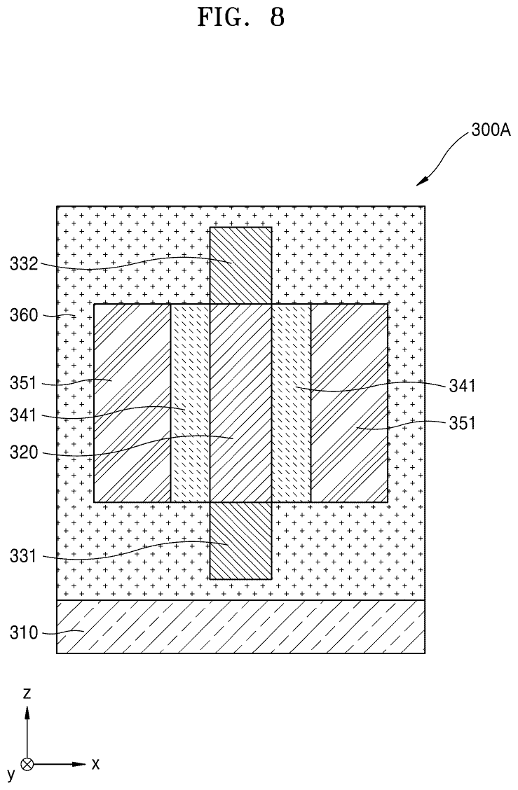

FIG. 8 illustrates a semiconductor device according to another example embodiment. Components of FIG. 8 using the same reference numerals as in FIG. 7 have substantially the same configuration and operational effects as the components described with reference to FIG. 7, and accordingly, detailed descriptions thereof are omitted here.

A semiconductor device 300A includes a source electrode 331, a channel 320, and a drain electrode 332 arranged in a direction (the z direction) perpendicular to the substrate 310. A gate insulating layer 341 may be provided around the channel 320, and a gate electrode 351 may be provided around the gate insulating layer 341. The gate electrode 351 may be provided around the channel 320 to increase an area where the gate electrode 351 faces the channel 320, and accordingly, a short channel effect may be improved. The semiconductor device 300A may be applied to a gate all-around transistor.

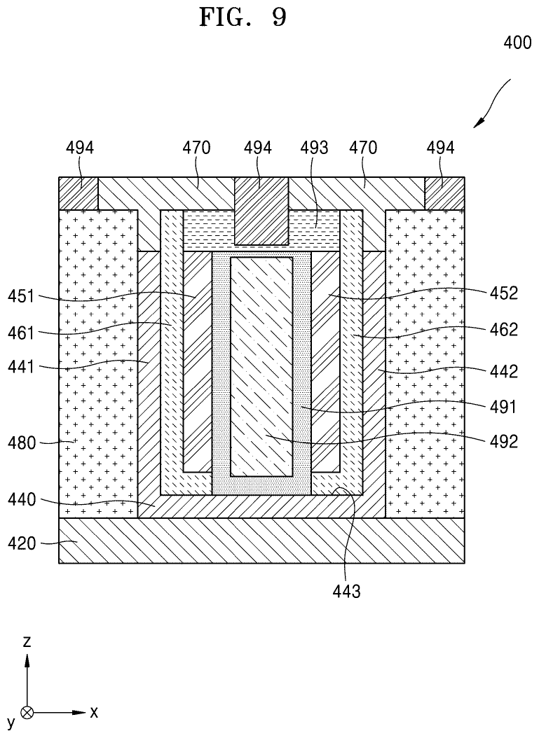

FIG. 9 Illustrates a Semiconductor Device According to Another Example embodiment.

Referring to FIG. 9, a semiconductor device 400 may include a source electrode 420 and a channel 440 provided on the source electrode 420. The channel 440 may include TeₐSe_{b}O_{c} (a+b+c=100, 40≤a<100, 0<b≤30, and 0<c≤30). The channel 440 may further include at least one of S, Se, In, Ge, Sn, Cu, Sb, As, B, P, or Al.

The channel 440 may have a U-shaped cross-sectional view. The channel 440 may include a bottom portion 443 connected to the source electrode 420, a first vertical extension portion 441 extending from one end of the bottom portion 443 in a direction (the z direction) perpendicular to the source electrode 420, and a second vertical extension portion 442 extending from the other end of the bottom portion 443 in a direction (the z direction) perpendicular to the source electrode 420.

A first gate electrode 451 may be spaced apart from the first vertical extension portion 441, and a second gate electrode 452 may be spaced apart from the second vertical extension portion 442. A first gate insulating layer 461 may be provided between the first vertical extension portion 441 and the first gate electrode 451, and a second gate insulating layer 462 may be provided between the second vertical extension portion 442 and the second gate electrode 452.

At least one of the first gate electrode 451 or the second gate electrode 452 may extend in a second horizontal direction (y). The first gate electrode 451 may be spaced apart from the second gate electrode 452. At least one of the first gate electrode 451 or the second gate electrode 452 may form a word line WL. An electrical signal input to the first gate electrode 451 may not match an electrical signal input to the second gate electrode 452. The first gate electrode 451 may control the first vertical extension portion 441 of the channel 440, and the second gate electrode 452 may control the second vertical extension portion 442 of the channel 440.

An insulating liner 491 may be between the first gate electrode 451 and the second gate electrode 452 that are spaced apart from each other. The insulating liner 491 may be conformally arranged on facing sidewalls of the first gate electrode 451, the second gate electrode 452 and/or an upper surface of the channel 440. The insulating liner 491 may have an upper surface arranged on the same plane as the first gate electrode 451 and the second gate electrode 452. The insulating liner 491 may include, for example, silicon nitride. A buried insulating layer 492 may fill a space between the first gate electrode 451 and the second gate electrode 452 that are spaced apart from each other, on the insulating liner 491. The buried insulating layer 492 may include, for example, silicon oxide. An upper insulating layer 493 may be on upper surfaces of the first gate electrode 451, the second gate electrode 452, and/or the buried insulating layer 492. An upper surface of the upper insulating layer 493 may be at the same level as an upper surface of a mold insulating layer 480.

Drain electrodes 470 may be on an upper surface of the channel 440. The drain electrodes 470 may serve as landing pads. The drain electrodes 470 may include a left drain electrode and a right drain electrode. The left drain electrode may be electrically connected to the first vertical extension portion 441. The right drain electrode may be electrically connected to the second vertical extension portion 442. The left drain electrode may not be electrically connected to the right drain electrode. The drain electrodes 470 may include upper portions and lower portions. The upper portion of each of the drain electrodes 470 may be a part of each of the drain electrodes 470 that are at a level higher than an upper surface of the mold insulating layer 480. The lower portion of each of the drain electrodes 470 may be a part of each of the drain electrodes 470 that are inside a drain electrode recess defined between the mold insulating layer 480 and the upper insulating layer 493. In one example embodiment, the upper portion of each of the drain electrodes 470 may have a first width in the first horizontal direction x, and the lower portion of each of the drain electrode 470 may have a second width that is less than the first width in the first horizontal direction x. The lower portion of each of the drain electrodes 470 may be inside the drain electrode recess, and the upper portion of each of the drain electrodes 470 may have a bottom surface arranged on an upper surface of the mold insulating layer 480 and an upper surface of the upper insulating layer 493, on the lower portion of each of the drain electrode 470, and accordingly, the drain electrodes 470 may each have a vertical cross-section having a T shape. The bottom surface of the lower portion of each of the drain electrodes 470 may be in contact with a corresponding one of an upper surface of the first vertical extension portion 441 and an upper surface of the second vertical extension portion 442. Both sidewalls of the lower portion of each of the drain electrodes 470 may be aligned with a corresponding one of both sidewalls of the first vertical extension portion 441 and both sidewalls of the second vertical extension portion 442. A bottom surface of the lower portion of each of the drain electrodes 470 may be at a level higher than an upper surface of the first gate electrode 451 and/or an upper surface of the second gate electrode 452, and a part of the sidewall of the lower portion of each of the drain electrodes 470 may be covered by the first gate insulating layer 461 and/or the second gate insulating layer 462. A drain electrode insulating layer 494 surrounding the drain electrodes 470 may be on an upper surface of the mold insulating layer 480 and the upper insulating layer 493. The semiconductor device 400 may have a vertical channel transistor (VCT) structure including a vertical channel region in which the channel 440 extends to the source electrode 420 in the vertical direction z.

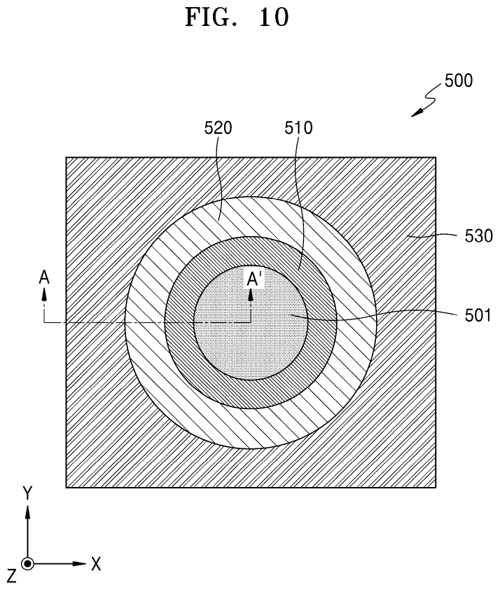

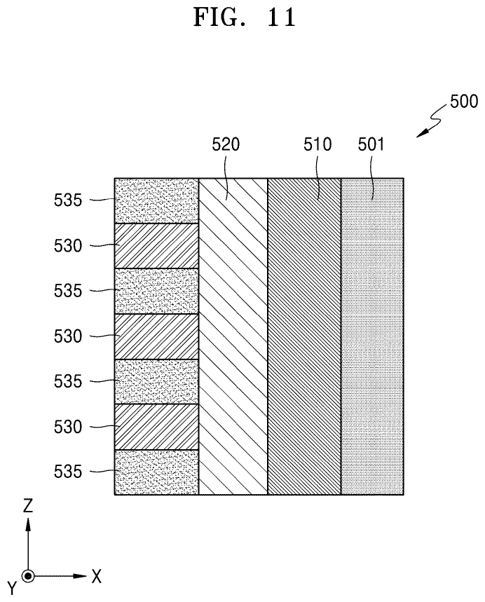

FIGS. 10 and 11 are respectively a horizontal cross-sectional view and a vertical cross-sectional view schematically illustrating a structure of a memory cell string of a memory device according to an example embodiment. Referring to FIG. 10, a memory cell string of a memory device (or a semiconductor device) 500 according to an example embodiment may include a center filler 501, a channel 510, a ferroelectric layer 520, and a gate electrode 530 arranged in a concentric shape on an XY plane. The channel 510 may include TeₐSe_{b}O_{c} (a+b+c=100, 40≤a<100, 0<b≤30, and 0<c≤30).

The channel 510 may surround the center filler 501, the ferroelectric layer 520 may surround the channel 510, and the gate electrode 530 may surround the ferroelectric layer 520. The center filler 501 may fill a space on an inner wall side of the channel 510 to support the channel 510 and a memory cell string. However, the center filler 501 is not an essential component and may be omitted. In this case, a free space may be provided instead of the center filler 501.

FIG. 11 schematically illustrates a cross-sectional view taken along line A-A′ of FIG. 10 from the center of the center filler 501 to the gate electrode 530 in the first direction (that is, the z-axis direction). Referring to FIG. 11, the memory device 500 includes a plurality of gate electrodes 530, and the plurality of gate electrodes 530 may be spaced apart from each other in the first direction. In addition, a plurality of spacers 535 may be between the plurality of gate electrodes 530. That is, the plurality of gate electrodes 530 and the plurality of spacers 535 may be alternately arranged in the first direction. The memory device 500 may include a channel 510 that faces and is spaced apart from the plurality of gate electrodes 530 and the plurality of spacers 535 in the second direction (that is, the X-axis direction) perpendicular to the first direction and extends continuously in the first direction, and the ferroelectric layer 520 that extends continuously in the first direction and is arranged between the channel 510 and the plurality of gate electrodes 530. Also, the memory device 500 may further include a center filler 501 that extends continuously in the first direction inside the channel 510. That is, the ferroelectric layer 520, the channel 510, and the center filler 501 may be sequentially arranged in the second direction from a plurality of gate electrodes 530 and the plurality of spacers 535. The plurality of spacers 535 may each include silicon oxide (SiO₂) with insulating properties but are not limited thereto.

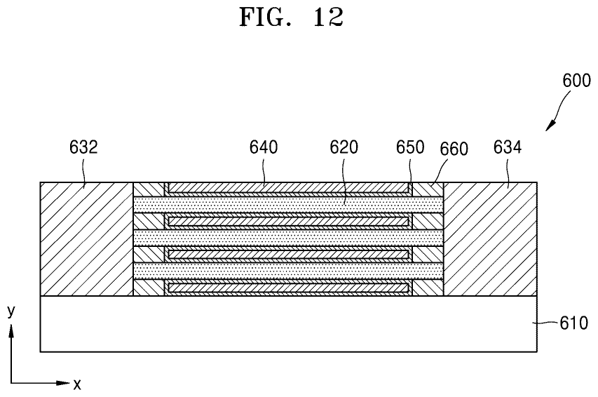

FIG. 12 is a view illustrating a semiconductor device 600 according to an example embodiment. The semiconductor device 600 includes a plurality of channels 620 arranged on a substrate 610, a source electrode 632 and a drain electrode 634 in contact with the channels 620, and a plurality of gate electrodes 640 spaced apart from the plurality of channels 620. The plurality of channels 620 may each include TeₐSe_{b}O_{c} (a+b+c=100, 40≤a<100, 0<b≤30, and 0<c≤30).

The substrate 610 may be an insulating substrate, or may be a semiconductor substrate having an insulating layer formed on a surface. The semiconductor substrate may include, for example, Si, Ge, SiGe, or so on. The substrate 610 may be, for example, a silicon substrate having a silicon oxide formed on a surface but is not limited thereto.

The source electrode 632 may be spaced apart from the drain electrode 634 in a first direction (the X direction) on the substrate 610, and the plurality of channels 620 may be spaced apart from each other in a second direction (the Y direction) between the source electrode 632 and the drain electrode 634.

The plurality of gate electrodes 640 may be spaced apart from the plurality of channels 620, respectively, and a ferroelectric layer 650 may be between the gate electrode 640 and the channel 620. For example, the ferroelectric layer 650 may be arranged to surround at least part of the gate electrode 640. For example, the plurality of gate electrodes 640 and the plurality of channels 620 may be alternately arranged in the second direction (the Y direction), and the ferroelectric layer 650 may have a form that surrounds the gate electrode 640. The ferroelectric layer 650 may provide insulation between the channel 620 and the gate electrode 640 and may suppress a leakage current.

A contact between each of the plurality of channels 620, the source electrode 632, and the drain electrode 634 may be an edge contact. For example, both ends of the channel 620 may be in contact with the source electrode 632 and the drain electrode 634, respectively.

In addition, the plurality of gate electrodes 640 are spaced apart from the source electrode 632 and the drain electrode 634, and a plurality of spacers 660 may be further arranged between the plurality of gate electrodes 640 and the source electrode 632 and between the plurality of gate electrodes 640 and the drain electrode 634. Because the source electrode 632, the plurality of gate electrodes 640, and the drain electrode 634 are arranged in the first direction (the x direction), parasitic capacitors may be generated between the source electrode 632 and the plurality of gate electrodes 640 and between the plurality of gate electrodes 640 and the drain electrode 634. In order to reduce the parasitic capacitors, the plurality of spacers 660 may each include, for example, a boron nitride film. Because the boron nitride film has no porosity and a mechanical strength, the boron nitride film may safely support the channel 620 on an upper layer (e.g., an upper surface) of the spacer 660.

The semiconductor device 600 may have a multi-bridge form in which the plurality of channels 620 are in contact with the source electrode 632 and the drain electrode 634 and are stacked to be spaced apart from each other in a direction away from the substrate 610. The plurality of channels 620 of the multi-bridge form may reduce a short channel effect and/or reduce areas occupied by source and drain electrodes. Thus, it is advantageous for relatively high integration. Further, it is possible to maintain uniform source/drain junction capacitance regardless of positions of channels, and thus, there is an advantage of being applicable to a relatively high-speed and/or relatively high-reliability device. The semiconductor device 600 may be applied to a so-called gate all around (GAA) transistor. The semiconductor device 600 may be applied to, for example, a logic device or a memory device.

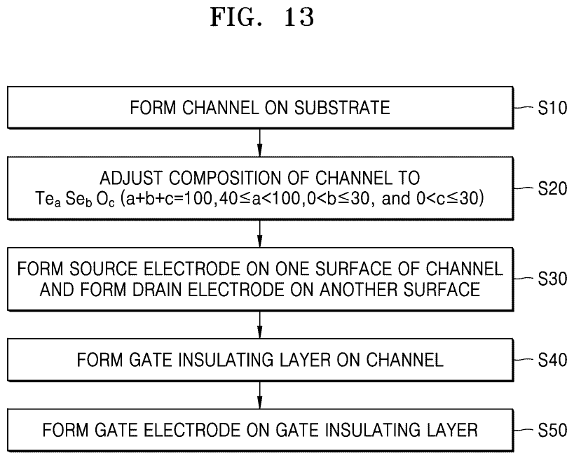

FIG. 13 is a flowchart illustrating a method of manufacturing a semiconductor device, according to an example embodiment.

Referring to FIG. 13, the method of manufacturing a semiconductor device includes forming a channel in a substrate (S10). The method of forming the channel may include a physical vapor deposition method, a chemical vapor deposition method, or an atomic layer deposition method. A composition of the channel is adjusted by TeₐSe_{b}O_{c} (a+b+c=100, 40≤a<100, 0<b≤30, and 0<c≤30) (S20).

A source electrode is formed on one surface of the channel, and a drain electrode is formed on the other surface (S30). In addition, a gate insulating layer is formed on the channel (S40). A gate electrode is formed on the gate insulating layer (S50). As described above, a semiconductor device having a p-type channel may be manufactured.

The forming of the channel may include preparing a first target including TeO, a second target including Te, and a third target including Se in a chamber. In addition, the first target, the second target, and the third target may be sputtered in a gas atmosphere. The gas may include, for example, Ar gas. The first target, the second target, and the third target may be prepared in the same chamber, and the first target, the second target, and the third target may be sputtered in a gas atmosphere. A deposition amount of O in TeO of the first target may be adjusted. In this process, a single-layer channel including TeSeO may be formed. In some example embodiments, a multi-layer channel, in which a Te layer, a TeO layer, and a Se layer are alternately stacked, may be formed. In this way, the present example embodiment may use a co-sputtering method in which multiple targets are used. Although a method of using three targets is described above, it is also possible to form a channel by using a first target including TeO, a second target including Te, a third target including Se, and a fourth target including SeO. In this case, a single-layer channel including TeSeO may be formed, or a multi-layer channel, in which a Te layer, a TeO layer, a Se layer, and an SeO layer are alternately stacked, may be formed.

As described above, the method of manufacturing a semiconductor device, according to the example embodiment, may form a p-type channel including Te, Se, and O by using a plurality of targets.

The semiconductor device according to the example embodiment may have excellent or improved on-current and/or mobility, and thus, the semiconductor device may be applied to various electronic apparatuses, such as 2T0C dynamic random access memory (DRAM), a monolithic 3D (M3D) logic circuit, a display, and a gas sensor, and so on.

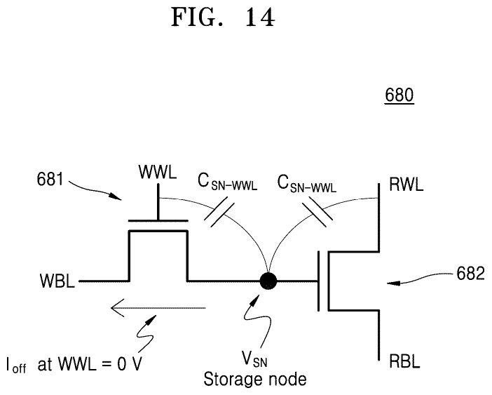

FIG. 14 illustrates an example in which a semiconductor device according to an example embodiment is applied to a memory device. Referring to FIG. 14, a memory device 680 may include a first transistor 681 and a second transistor 682. The memory device 680 may be a so-called 2T0C DRAM. That is, the memory device 680 may have a structure including two transistors and no capacitor. The memory device 680 may store and read data by using the first transistor 681 and the second transistor 682 and may maintain the data without a capacitor. One of the semiconductor devices 100, 300, 300A, 400, 500, and 600 described with reference to FIGS. 1 to 12 may be applied to at least one of the first transistor 681 or the second transistor 682. One of the first transistor 681 or the second transistor 682 may be used as a write transistor, and the other may be used as a read transistor. Hole mobility is important for a read transistor. The channels 120, 320, 440, 510, and 620 of the semiconductor devices 100, 300, 300A, 400, 500, and 600 according to some example embodiments may have relatively high hole mobility and/or have a relatively high on/off ratio by adjusting an oxygen composition to increase conductivity, and thus, the channels 120, 320, 440, 510, and 620 may be usefully applied to 2T0C DRAM.

In FIG. 14, RWL represents a read word line, RBL represents a read bit line, WWL represents a write word line, and WBL represents a write bit line.

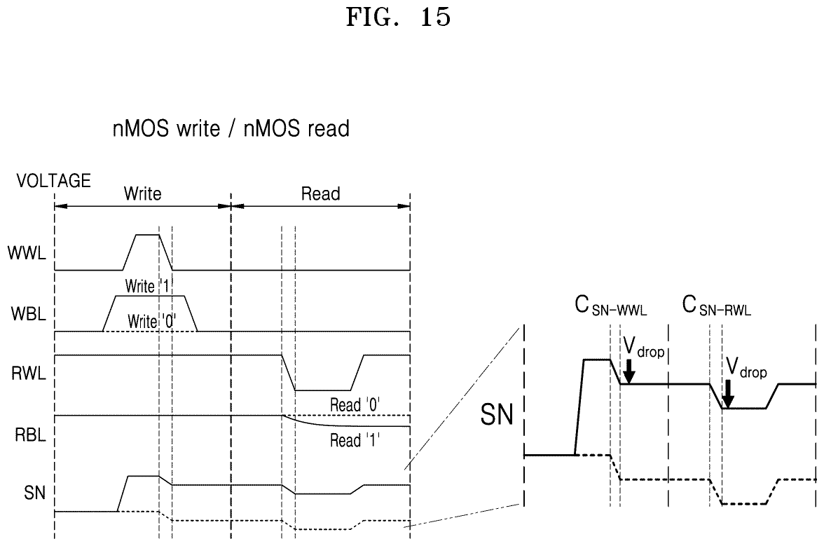

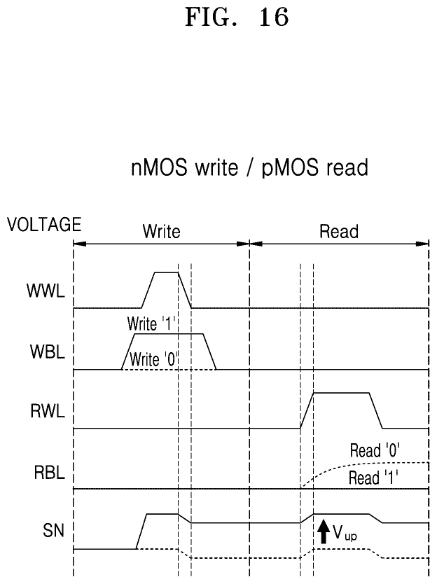

FIG. 15 illustrates voltages of respective electrical lines of a unipolar 2T0C DRAM based on an n-type channel. The unipolar 2T0C DRAM based on the n-type channel may include an n-type metal oxide semiconductor (MOS) transistor for writing and an n-type MOS transistor for reading. In this case, a voltage drop occurs in a storage node (SN) during a write operation and a read operation due to capacitance coupling, resulting in power loss. FIG. 16 illustrates voltages of respective electrical lines in 2TOC DRAM including an n-type MOS transistor and a p-type MOS transistor. One of the semiconductor devices 100, 300, 300A, 400, 500, and 600 according to the above embodiments may be applied to the p-type MOS transistor. As illustrated in FIG. 16, the 2T0C DRAM based on the p-type channel, according to an example embodiment, may reduce the capacitance coupling, and accordingly, a read operation may be performed without a voltage drop.

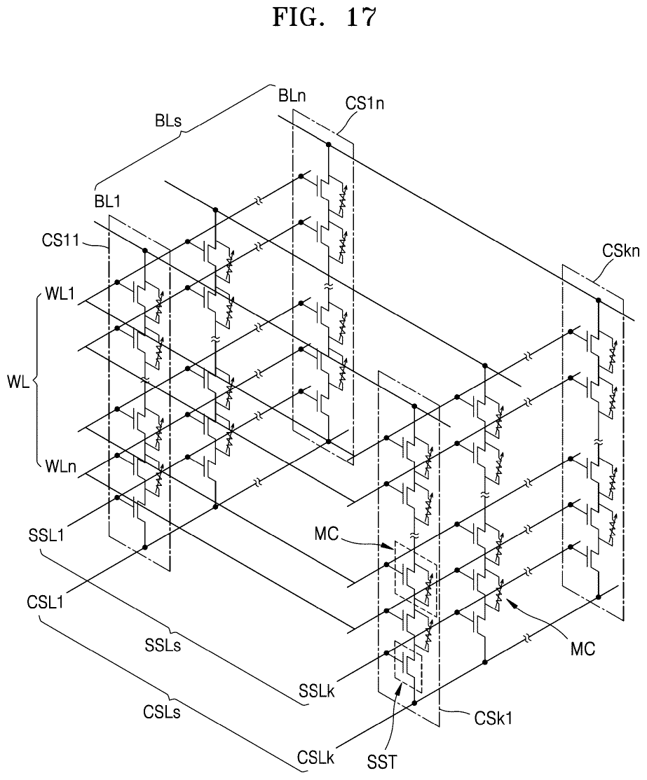

FIG. 17 is a diagram illustrating an equivalent circuit of a memory device according to an example embodiment.

Referring to FIG. 17, the memory device may include a plurality of memory cell strings CS11 to CSkn. The plurality of memory cell strings CS11 to CSkn may be two-dimensionally arranged in a row direction and a column direction to form rows and columns. The plurality of memory cell strings CS11 to CSkn may each include a plurality of memory cells MC and a string select transistor SST. The plurality of memory cells MC and the string select transistor SST included in each of the plurality of memory cell strings CS11 to CSkn may be stacked in a height direction. The plurality of memory cells MC included in each of the plurality of memory cell strings CS11 to CSkn may each correspond to a circuit including a transistor and a resistor connected in parallel. For example, each of the plurality of memory cell strings CS11 to CSkn may be the memory cell string illustrated in FIGS. 10 and 11.

Rows of the plurality of memory cell strings CS11 to CSkn may be connected to different string select lines SSL1 to SSLk, respectively. For example, the string select transistors SST of the plurality of memory cell strings CS11 to CS1n may be commonly connected to the string select line SSL1. The string select transistors SST of the plurality of memory cell strings CSk1 to CSkn may be commonly connected to the string select line SSLk.

Also, columns of the plurality of memory cell strings CS11 to CSkn may be connected to different bit lines BL1 to BLn, respectively. For example, the plurality of memory cells MC and the string select transistors SST included in the plurality of memory cell strings CS11 to CSk1 may be commonly connected to the bit line BL1, and the plurality of memory cells MC and the string select transistors SST included in the plurality of memory cell strings CS1n to CSkn may be commonly connected to the bit line BLn.

Also, rows of the plurality of memory cell strings CS11 to CSkn may be connected to different common source lines CSL1 to CSLk, respectively. For example, the string select transistors SST of the plurality of memory cell strings CS11 to CS1n may be commonly connected to the common source line CSL1, and the string select transistors SST of the plurality of memory cell strings CSk1 to CSkn may be commonly connected to the common source line CSLk.

The memory cells MC located at the same height from a substrate (or the string select transistors SST may be commonly connected to one word line WL, and the memory cells MC located at different heights may be connected to different word lines WL1 to WLm.

In this structure, writing and reading may be performed in units of rows of the memory cell strings CS11 to CSkn. For example, the memory cell strings CS11 to CSkn may be selected in units of rows by the common source lines CSLs, and the memory cell strings CS11 to CSkn may be selected in units of rows by the string select lines SSLs. In addition, in the selected row of the plurality of memory cell strings CS11 to CSkn, writing and reading may be performed in units of pages. For example, a page may be one row of the memory cells MC connected to one word line WL. In the selected row of the plurality of memory cell strings CS11 to CSkn, the memory cells MC may be selected in units of pages by the word lines WL.

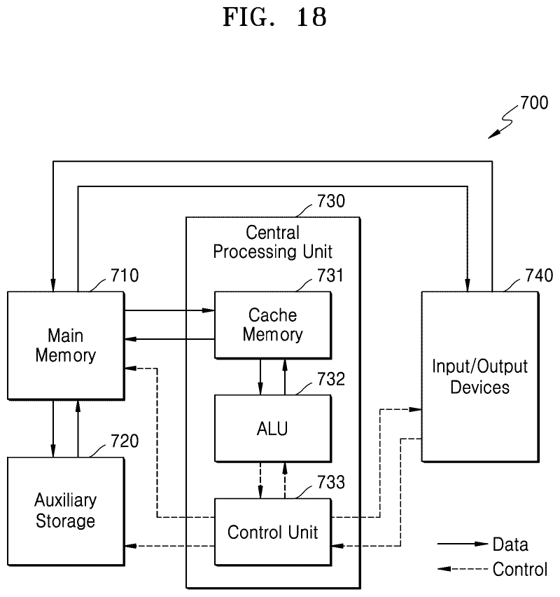

In addition, the semiconductor device 100 according to the example embodiment may be used for data storage in various electronic apparatuses. FIG. 18 is a conceptual diagram schematically illustrating a device architecture that may be applied to an electronic apparatus according to an example embodiment. Referring to FIG. 18, an electronic apparatus 700 may include a main memory 710, an auxiliary storage 720, a central processing unit (CPU) 730, and an input/output device 740. The CPU 730 may include a cache memory 731, an arithmetic logic unit (ALU) 732, and a control unit 733. The cache memory 731 may include static random access memory (SRAM). The main memory 710 may include a DRAM device, and the auxiliary storage 720 may include one of the semiconductor devices 100, 200, 300, 300A, 400, 500, and 600 according to the above example embodiments. In some example embodiments, the cache memory 731, the main memory 710, and the auxiliary storage 720 may each include one of the semiconductor devices 100, 200, 300, 300A, 400, 500, and 600 according to the above example embodiments. In some cases, the electronic apparatus 700 may be implemented in a form in which computing unit elements are adjacent to memory unit elements in one chip without distinction of the sub-units described above.

Some of the elements and/or functional blocks disclosed above may be implemented by hardware such as a processing circuit including a logic circuit, a hardware/software combination such as a processor execution software; or a combination thereof. For example, the processing circuit may include a CPU, an ALU, a digital signal processor, a microcontroller, a field programmable gate array (FPGA), a system-on-chip (SoC), a programmable logic unit, a microprocessor, an application-specific integrated circuit (ASIC), and so on. The processing circuit may include electronic components, such as at least one of a transistor, a resistor, a capacitor, and so on. The processing circuit may include electronic components including at least one logic gate, such as an AND gate, an OR gate, a NAND gate, a NOR gate, and so on.

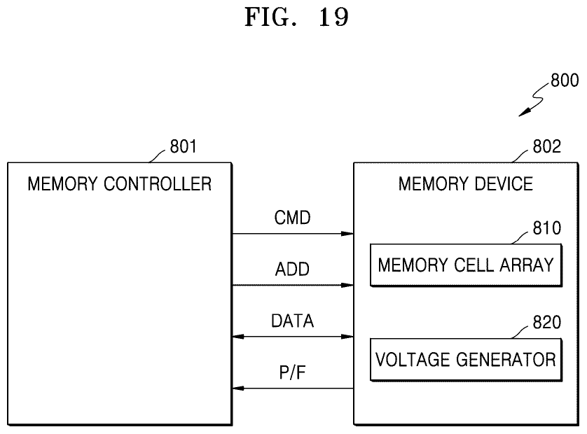

FIG. 19 is a block diagram of a memory system 800 according to an example embodiment.

Referring to FIG. 19, the memory system 800 may include a memory controller 801 and a memory device 802. The memory controller 801 performs a control operation for the memory device 802 and provides the memory device 802 with, for example, an address ADD and a command CMD for performing a programming (or write) operation, a read operation, and/or an erasure operation for the memory device 802. Also, data for the programming operation and read operation may be transmitted between the memory controller 801 and the memory device 802.

The memory device 802 may include a memory cell array 810 and a voltage generator 820. The memory cell array 810 may include a plurality of memory cells and may include one of the semiconductor devices 100, 200, 300, 300A, 400, 500, and 600 according to the above example embodiments described above.

The memory controller 801 may include hardware such as a processing circuit including a logic circuit; a hardware/software combination, such as processor execution software; or a combination thereof. More specifically, the processing circuit may include, for example, a CPU, an ALU, a digital signal processor, a microcontroller, an FPGA), a SoC, a programmable logic unit, a microprocessor, an ASIC, and so on but is not limited thereto. The memory controller 801 may operate in response to a request from a host (not illustrated) and may be converted into a special purpose controller by accessing the memory device 802 to perform control operations (for example, write and read operations) discussed above, the memory controller 801. The memory controller 801 may generate the address ADD and the command CMD for performing programming, read, and erasure operations for the memory cell array 810. Also, in response to a command from the memory controller 801, the voltage generator 820 (for example, a power circuit) may generate a voltage control signal for controlling a voltage level of a word line for data programming or data reading to the memory cell array 810.

Also, the memory controller 801 may perform a determination operation on the data read from the memory device 802. For example, the number of on-cells and/or the number of off-cells may be determined from the data read from memory cells. The memory device 802 may provide a pass/fail signal (P/F) to the memory controller 801 based on the read result on the read data. The memory controller 801 may control the write and read operations of the memory cell array 810 according to the pass/fail signal (P/F).

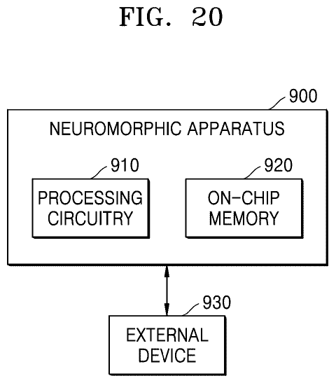

FIG. 20 is a block diagram illustrating a neuromorphic apparatus 900 according to an example embodiment and an external device connected thereto.

Referring to FIG. 20, the neuromorphic apparatus 900 may include a processing circuitry 910 and/or an on-chip memory 920. The on-chip memory 920 may include one of the semiconductor devices 100, 200, 300, 300A, 400, 500, and 600 according to the above example embodiments described above.

In some example embodiments, the processing circuitry 910 may be configured to control a function for driving the neuromorphic apparatus 900. For example, the processing circuitry 910 may be configured to control the neuromorphic apparatus 900 by executing a program stored in the on-chip memory 920. In some example embodiments, the processing circuitry 910 may include hardware such as a logic circuit, a hardware/software combination such as a processor executing software, or a combination thereof. For example, a processor may include a CPU, a graphics processing unit (GPU), an application processor (AP) included in the neuromorphic apparatus 900, an ALU, a digital signal processor, a microcontroller, a FPGA, a SoC, a programmable logic unit, a microprocessor, an ASIC, and so on but is not limited thereto. In some example embodiments, the processing circuitry 910 may be configured to read/write various data from/to an external device 930, and/or to execute the neuromorphic apparatus 900 by using the read/written data. In some example embodiments, the external device 930 may include an external memory and/or a sensor array having an image sensor (for example, a complementary metal oxide semiconductor (CMOS) image sensor circuit).

In some example embodiments, the neuromorphic apparatus 900 may be applied to a machine learning system. The machine learning system may use a variety of artificial neural network organization and processing models, such as a convolutional neural network (CNN), a deconvolutional neural network, a recurrent neural network (RNN) that optionally including a long short-term memory (LSTM) unit and/or a gated recurrent unit (GRU), a stacked neural network (SNN), a state-space dynamic neural network (SSDNN), a deep faith network (DBN), a generative adversarial network (GAN), and/or a restricted Boltzmann machine (RBM).

Alternatively or additionally, the machine learning system may include other forms of machine learning models, such as linear and/or logistic regression, statistical clustering, Bayesian classification, decision trees, dimensionality reduction such as principal component analysis, expert systems, and/or combinations thereof including ensembles such as random forests. These machine learning models may be used to provide various services and/or applications, such as image classification services, user authentication services based on biometric information or biometric data, advanced driver assistance system (ADAS) services, voice assistant services, and automatic speech recognition (ASR) services, which may be performed by electronic apparatuses.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The semiconductor devices according to the above example embodiments may be used for transistors, photovoltaic cells, thermoelectric devices, light-emitting diodes, displays, and so on, and may be used for DRAM, flash memory, CMOS image sensors, and so on.

The semiconductor devices according to the above example embodiments may implement a p-type channel including tellurium, selenium, and oxygen. The semiconductor devices according to the above example embodiments may exhibit p-type channel characteristics by controlling compositions of tellurium, selenium, and oxygen. Thus, the semiconductor devices according to the above example embodiments may be applied to various logic circuit elements, 2T0C DRAMs, and so on.

The example embodiments described above are merely examples, and those having common knowledge in the relevant technical field may make various modifications and equivalent other example embodiments therefrom. Therefore, the true technical protection scope according to the above example embodiments should be determined by the technical idea of the disclosure described in the following patent claims.

It should be understood that the example embodiments described herein should be considered in a descriptive sense only and not for purposes of limitation. Descriptions of features or aspects within each example embodiment should typically be considered as available for other similar features or aspects in other example embodiments. While one or more example embodiments have been described with reference to the figures, it will be understood by those of ordinary skill in the art that various changes in form and details may be made therein without departing from the spirit and scope as defined by the following claims.

What is claimed is:

1. A semiconductor device comprising:
a channel;
a source electrode electrically connected to the channel;
a drain electrode electrically connected to the channel and spaced apart from the source electrode;
a gate insulating layer on the channel; and
a gate electrode on the gate insulating layer,
wherein the channel includes TeₐSe_{b}O_{c} (a+b+c=100, 40≤a<100, 0<b≤30, and 0<c≤30).

2. The semiconductor device of claim 1, wherein the channel has a composition of 0.05≤(b/a)≤0.8.

3. The semiconductor device of claim 1, wherein the channel has a structure in which at least two layers of a tellurium layer, a tellurium oxide layer, a selenium layer, or a selenium oxide layer are alternately stacked.

4. The semiconductor device of claim 1, wherein the channel further includes at least one of S, Se, In, Ge, Sn, Cu, Sb, As, B, P, or Al.

5. The semiconductor device of claim 1, wherein
a first direction from the source electrode to the drain electrode is same as a vertical direction of the semiconductor device, and
longitudinal directions of the channel, the gate insulating layer, and the gate electrode are arranged in the first direction.

6. The semiconductor device of claim 1, wherein the channel includes a bottom portion in contact with the source electrode, a first vertical extension portion extending from one end of the bottom portion in a direction perpendicular to the source electrode, and a second vertical extension portion extending from another end of the bottom portion in a direction perpendicular to the source electrode.

7. The semiconductor device of claim 1, wherein
the channel, the gate insulating layer, and the gate electrode are arranged in a concentric shape, and
the gate electrode includes a first gate electrode and a second gate electrode that are spaced apart from each other, and a spacer is arranged between the first gate electrode and the second gate electrode.

8. The semiconductor device of claim 1, wherein the channel includes a plurality of channels, and has a multi-bridge shape in which the plurality of channels are in contact with the source electrode and the drain electrode and are stacked to be spaced apart from each other in a direction away from a substrate.

9. An electronic apparatus comprising:
a host;
a memory device including at least one semiconductor device; and
a memory controller configured to control the memory device for at least one of reading data from the memory device or writing data to the memory device, in response to a request from the host,
wherein the at least one semiconductor device includes a channel, a source electrode electrically connected to the channel, a drain electrode electrically connected to the channel and spaced apart from the source electrode, a gate insulating layer on the channel, and a gate electrode on the gate insulating layer, and
the channel includes TeₐSe_{b}O_{c} (a+b+c=100, 40≤a<100, 0<b≤30, and 0<c≤30).

10. The electronic apparatus of claim 9, wherein the channel has a composition of 0.05≤(b/a)≤0.8.

11. The electronic apparatus of claim 9, wherein the channel has a structure in which at least two layers of a tellurium layer, a tellurium oxide layer, a selenium layer, or a selenium oxide layer are alternately stacked.

12. The electronic apparatus of claim 9, wherein the channel further includes at least one of S, Se, In, Ge, Sn, Cu, Sb, As, B, P, or Al.

13. The electronic apparatus of claim 9, wherein
a first direction from the source electrode to the drain electrode is same as a vertical direction of the semiconductor device, and
longitudinal directions of the channel, the gate insulating layer, and the gate electrode are arranged in the first direction.

14. The electronic apparatus of claim 9, wherein the channel includes a bottom portion in contact with the source electrode, a first vertical extension portion extending from one end of the bottom portion in a direction perpendicular to the source electrode, and a second vertical extension portion extending from another end of the bottom portion in a direction perpendicular to the source electrode.

15. The electronic apparatus of claim 9, wherein the channel includes a plurality of channels, and has a multi-bridge shape in which the plurality of channels are in contact with the source electrode and the drain electrode and are stacked to be spaced apart from each other in a direction away from a substrate.

16. The electronic apparatus of claim 9, wherein
the channel, the gate insulating layer, and the gate electrode are arranged in a concentric shape, and
the gate electrode includes a first gate electrode and a second gate electrode that are spaced apart from each other, and a spacer is arranged between the first gate electrode and the second gate electrode.

17. The electronic apparatus of claim 9, wherein the memory device includes a dynamic random access memory (DRAM) device having a 2T0C structure.

18. A method of manufacturing a semiconductor device, the method comprising:
forming a channel on a substrate;
adjusting a composition of the channel to TeₐSe_{b}O_{c} (a+b+c=100, 40≤a<100, 0<b≤30, and 0<c≤30);
forming a source electrode on one surface of the channel and forming a drain electrode on another surface of the channel;
forming a gate insulating layer on the channel; and
forming a gate electrode on the gate insulating layer.

19. The method of claim 18, wherein the channel has a composition of 0.05≤(b/a)≤0.8.

20. The method of claim 18, wherein the channel has a structure in which at least two layers of a tellurium layer, a tellurium oxide layer, a selenium layer, or a selenium oxide layer are alternately stacked.
